(19) United States
(12) Patent Application Publication
(10) Pub. No.: US 2026/0173706 A1
(43) Pub. Date: Jun. 18, 2026

(54) DISPLAY MODULE AND MANUFACTURING METHOD THEREOF, DISPLAY DEVICE

(71) Applicants: Hefei Visionox Technology Co., Ltd., Hefei (CN); Kunshan Govisionox Optoelectronics Co., Ltd., Kunshan (CN)

(72) Inventors: Chao ZHU, Hefei (CN); Wenzhi FAN, Hefei (CN); Hui LI, Hefei (CN); Aowen ZHANG, Hefei (CN); Junxia CAI, Hefei (CN); Rubo XING, Hefei (CN)

(73) Assignees: Hefei Visionox Technology Co., Ltd., Hefei (CN); Kunshan Govisionox Optoelectronics Co., Ltd., Kunshan (CN)

(21) Appl. No.: 19/531,574

(22) Filed: Feb. 5, 2026

Related U.S. Application Data
(63) Continuation of application No. PCT/CN2024/097149, filed on Jun. 4, 2024.

(30) Foreign Application Priority Data
Aug. 10, 2023 (CN) 202311018356.3

(51) Int. Cl. H10K 59/38; H10K 59/12; H10K 59/80

(52) U.S. Cl. CPC H10K 59/38; H10K 59/1201; H10K 59/873

(57) ABSTRACT

Embodiments of the present application provide a display module, a preparation method thereof, and a display device. The display module includes: a substrate; a light-emitting layer, disposed on one side of the substrate, the light-emitting layer including a plurality of light-emitting units; a filter layer, disposed on a side of the light-emitting layer away from the substrate, the filter layer including a light-shielding portion and a filter opening, a filter unit is disposed in the filter opening, an orthographic projection of the filter unit on the substrate at least partially overlaps with an orthographic projection of the light-emitting unit on the substrate; and an avoidance groove is provided on the light-shielding portion, a filling unit is disposed in the avoidance groove, the filling unit is configured to allow light within a first waveband to pass through, and the filling unit is configured to filter light within a second waveband.

### CROSS-REFERENCE TO RELATED APPLICATION

The present application is a continuation of International Application No. PCT/CN2024/097149 filed on Jun. 4, 2024, which claims priority to Chinese Patent Application No. 202311018356.3, entitled “DISPLAY MODULE AND MANUFACTURING METHOD THEREOF, DISPLAY DEVICE” and filed on Aug. 10, 2023, the entire contents of which are incorporated herein by reference.

### FIELD

The present application relates to the technical field of display devices, and in particular, to a display module and a manufacturing method thereof, and a display device.

### BACKGROUND

With the rapid development of electronic devices, users have increasingly higher requirements for screen-to-body ratios, making full-screen displays of electronic devices receive more and more attention in the industry.

Traditional electronic devices such as mobile phones and tablet computers require high transmittance for display devices due to the need to integrate components such as front infrared sensing elements and fingerprint recognition elements. Currently, light-shielding elements such as black matrices need to be arranged in the filter layer on the display device, which seriously affects the transmittance of the display device.

### SUMMARY

Embodiments of the present application provide a display module and a manufacturing method thereof, and a display device, aiming to improve the transmittance of the display module.

An embodiment of the present application provides a display module, including: a substrate; a light-emitting layer disposed on one side of the substrate, the light-emitting layer including a plurality of light-emitting units; a filter layer disposed on a side of the light-emitting layer away from the substrate, the filter layer including a light-shielding portion and filter openings, and a filter unit is disposed within the filter opening, and an orthographic projection of the filter unit on the substrate at least partially overlaps with an orthographic projection of the light-emitting unit on the substrate; and a recess is provided on the light-shielding portion, a filling unit is disposed within the recess, the filling unit is configured to allow light within a first wavelength band to pass through, and the filling unit is configured to filter light within a second wavelength band, the first wavelength band and the second wavelength band at least partially do not overlap.

An embodiment of the present application provides a method for manufacturing a display module, including:
forming a light-emitting layer on a substrate, the light-emitting layer including a plurality of light-emitting units;
forming a light-shielding material layer on a side of the light-emitting layer away from the substrate, and patterning the light-shielding material layer to form a light-shielding portion, filter openings, and a recess, and an orthographic projection of the filter opening on the substrate at least partially overlaps with an orthographic projection of the light-emitting unit on the substrate;
disposing a filter unit within the filter opening, and disposing a filling unit within the recess, the filling unit being configured to allow light within a first wavelength band to pass through, and the filling unit being configured to filter light within a second wavelength band, the first wavelength band and the second wavelength band at least partially do not overlap.

An embodiment of the present application provides a display device, including: the display module according to any of the preceding embodiments; a photosensitive element disposed on a side of the substrate away from the light-emitting layer, the photosensitive element being configured to receive light information within the first wavelength band.

In the display module provided by the embodiments of the present application, the display module includes a substrate, a light-emitting layer, and a filter layer. The light-emitting layer includes light-emitting units, which are used for emitting light to achieve light-emitting display of the display module. The filter layer includes a light-shielding portion and filter units. The filter units can filter stray light, improving the display effect of the display module. A filling unit is also disposed within the recess of the light-shielding portion. The filling unit can allow light within a first wavelength band to pass through, ensuring the transmittance of the display module. When a photosensitive element is disposed on the non-display side of the display module, the photosensitive element can acquire light information within the first wavelength band, without affecting the normal operation of the photosensitive element. Furthermore, the filling unit can also filter light within a second wavelength band, enabling the filling unit to block the propagation of at least part of the light within the second wavelength band. In the screen-off state of the display module, the display difference between the area where the filling unit is located and other areas can be reduced, improving the display effect of the display module in the screen-off state. Therefore, by disposing the filling unit within the recess, the present application can not only improve the transmittance of the display module but also ensure the display effect of the display module in the screen-off state.

### BRIEF DESCRIPTION OF THE DRAWINGS

Other features, purposes, and advantages of the present application will become more apparent by reading the detailed description of non-limiting embodiments with reference to the accompanying drawings, and the same or similar reference numerals denote the same or similar features.

FIG. 1 is a top view schematic diagram of a display module according to an embodiment provided by the present application;

FIG. 2 is a schematic diagram of a partially enlarged structure of a display module according to an embodiment provided by the present application;

FIG. 3 is a cross-sectional view of a display module according to an embodiment provided by the present application;

FIG. 4 is a schematic diagram of a partially enlarged structure of a display module according to another embodiment provided by the present application;

FIG. 5 is a filtering curve diagram of a red filling unit of a filter layer of a display module for light of different wavelength bands according to an embodiment provided by the present application;

FIG. 6 is a filtering curve diagram of a green filling unit of a filter layer of a display module for light of different wavelength bands according to an embodiment provided by the present application;

FIG. 7 is a filtering curve diagram of a blue filling unit of a filter layer of a display module for light of different wavelength bands according to an embodiment provided by the present application;

FIG. 8 is a schematic diagram of a partially enlarged structure of a display module according to yet another embodiment provided by the present application;

FIG. 9 is a schematic diagram of a partially enlarged structure of a display module according to still another embodiment provided by the present application;

FIG. 10 is a cross-sectional view of a display module according to another embodiment provided by the present application;

FIG. 11 is a schematic diagram of a partially enlarged structure of a display module according to a further embodiment provided by the present application;

FIG. 12 is a flowchart of a method for manufacturing a display module according to an embodiment provided by the present application;

FIG. 13 is a partial cross-sectional view of a display device according to an embodiment provided by the present application.

### DETAILED DESCRIPTION

The features and exemplary embodiments of various aspects of the present application will be described in detail below. In the following detailed description, numerous specific details are set forth to provide a thorough understanding of the present application. However, it will be apparent in the art that the present application may be practiced without some of these specific details. The description of the embodiments below is merely intended to provide a better understanding of the present application by illustrating examples thereof. In the drawings and the following description, at least some well-known structures and techniques are not shown to avoid unnecessarily obscuring the present application; and for clarity, the dimensions of some structures may be exaggerated. Furthermore, the features, structures, or characteristics described below may be combined in any suitable manner in one or more embodiments.

In the description of the present application, it should be noted that, unless otherwise specified, “a plurality of” means two or more; terms such as “upper”, “lower”, “left”, “right”, “inner”, “outer”, etc., indicating orientation or positional relationships are merely for convenience in describing the present application and simplifying the description, and do not indicate or imply that the referred device or element must have a specific orientation or be constructed and operated in a specific orientation, and thus should not be construed as limiting the present application. In addition, terms such as “first”, “second”, etc., are used for descriptive purposes only and should not be construed as indicating or implying relative importance.

The directional terms appearing in the following description refer to the directions shown in the drawings and are not intended to limit the specific structure of the embodiments of the present application. In the description of the present application, it should also be noted that, unless otherwise explicitly specified and defined, the terms “mount”, “connect”, etc., should be understood broadly, for example, they may be fixed connections, detachable connections, or integral connections; they may be direct connections or indirect connections. For those of ordinary skill in the art, the specific meanings of the above terms in the present application can be understood according to specific circumstances.

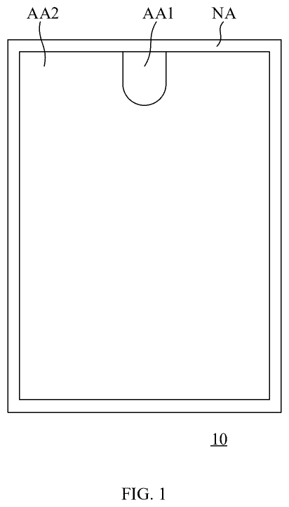

To better understand the present application, a display module, a method for preparing the same, and a display device according to embodiments of the present application will be described in detail below with reference to FIG. 1 to FIG. 11.

An embodiment of the present application provides a display module, which is an Organic Light Emitting Diode (OLED) display module.

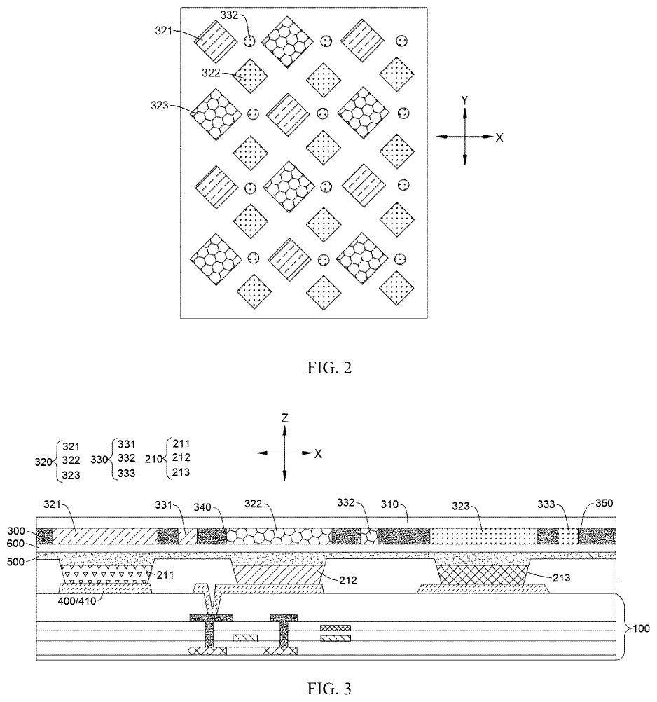

Please refer to FIG. 1 to FIG. 3 together. FIG. 1 shows a top view schematic diagram of a display module 10 according to an embodiment of the present application. FIG. 2 shows a partially enlarged structural schematic diagram of the display module 10 according to an embodiment of the present application. FIG. 3 shows a cross-sectional view of the display module 10 according to an embodiment of the present application.

As shown in FIG. 1 to FIG. 3, an embodiment of the present application provides a display module 10. The display module 10 includes a substrate 100, a light-emitting layer 200, and a filter layer 300. The light-emitting layer 200 is disposed on one side of the substrate 100, and the light-emitting layer 200 includes a plurality of light-emitting units 210. The filter layer 300 is disposed on a side of the light-emitting layer 200 away from the substrate 100. The filter layer 300 includes a light-shielding portion 310 and filter openings 340. A filter unit 320 is disposed in the filter opening 340. An orthographic projection of the filter unit 320 on the substrate 100 at least partially overlaps with an orthographic projection of the light-emitting unit 210 on the substrate 100. A recess 350 is provided on the light-shielding portion 310. A filling unit 330 is disposed in the recess 350. The filling unit 330 is configured to allow light within a first wavelength band to pass through and to filter light within a second wavelength band. The first wavelength band and the second wavelength band at least partially do not overlap.

In the display module 10 provided by the embodiment of the present application, the display module 10 includes the substrate 100, the light-emitting layer 200, and the filter layer 300. The light-emitting layer 200 includes the light-emitting units 210, which are used for emitting light to achieve light-emitting display of the display module 10. The filter layer 300 includes the light-shielding portion 310 and the filter units 320. The filter units 320 can filter stray light, improving the display effect of the display module 10. The filling unit 330 is further disposed in the recess 350 of the light-shielding portion 310. The filling unit 330 allows light within the first wavelength band to pass through, which improves the light transmittance of the display module 10 in the area where the recess 350 is located. When a photosensitive element is disposed on the non-display side of the display module 10, the photosensitive element can acquire light information within the first wavelength band passing through the filling unit 330, without affecting the normal use of the photosensitive element. Furthermore, the filling unit 330 also filter light within the second wavelength band, enabling the filling unit 330 to hinder the propagation of at least part of the light within the second wavelength band. When the display module 10 is in a screen-off state, the display difference between the area where the filling unit 330 is located and other areas can be reduced, improving the display effect of the display module 10 in the screen-off state. Therefore, by providing the filling unit 330 in the recess 350, the present application can not only ensure the light transmittance of the display module 10 but also ensure the display effect of the display module 10 in the screen-off state.

There are various ways to arrange the substrate 100. For example, the substrate 100 may include a base substrate, and a first conductive layer, a second conductive layer, and a third conductive layer that are sequentially stacked on one side of the base substrate. An insulating layer is disposed between adjacent conductive layers. Exemplarily, the pixel driving circuit disposed on the substrate 100 includes a transistor and a storage capacitor. The transistor includes a semiconductor, a gate, a source, and a drain. The storage capacitor includes a first electrode plate and a second electrode plate. As an example, the gate and the first electrode plate may be located in the first conductive layer, the second electrode plate may be located in the second conductive layer, and the source and the drain may be located in the third conductive layer. In other embodiments, the substrate 100 may include a first conductive layer, a second conductive layer, a third conductive layer, and a fourth conductive layer.

In one embodiment, a pixel definition layer is disposed on the substrate 100. The pixel definition layer includes pixel defining portions and pixel openings defined by the pixel defining portions. The light-emitting unit 210 may be disposed in the pixel openings. The light-emitting unit 210 may include a red light-emitting unit 211, a green light-emitting unit 212, and a blue light-emitting unit 213.

In one embodiment, a first electrode layer 400 is disposed on the substrate 100. The first electrode layer 400 includes a plurality of first electrodes 410 arranged in an array. The plurality of first electrodes 410 are spaced apart. Each first electrode 410 corresponds to a respective pixel opening, enabling the first electrode 410 to act on the light-emitting unit 210 within the pixel opening to cause it to emit light for display.

In one embodiment, a second electrode 500 is disposed on a side of the light-emitting layer 200 facing away from the substrate 100. The second electrode 500 may be a common electrode. The second electrode 500 and the first electrode 410 interact to drive the light-emitting unit 210 to emit light for display. In one embodiment, an encapsulation layer 600 is disposed on a side of the second electrode 500 facing away from the substrate 100. The encapsulation layer 600 is used to encapsulate the light-emitting unit 210, mitigating the impact of moisture and oxygen ingress on the light-emitting unit 210.

In one embodiment, a color filter layer 300 is disposed on a side of the encapsulation layer 600 facing away from the substrate 100 to ensure the encapsulation effect.

There are various ways to arrange the color filter units 320. In one embodiment, the color filter units 320 include a red color filter unit 321, a green color filter unit 322, and a blue color filter unit 323. The red color filter unit 321 corresponds to the red light-emitting unit 211, the green color filter unit 322 corresponds to the green light-emitting unit 212, and the blue color filter unit 323 corresponds to the blue light-emitting unit 213. The correspondence between the red color filter unit 321 and the red light-emitting unit 211 means that the orthographic projection of the red light-emitting unit 211 on the substrate 100 at least partially overlaps with the orthographic projection of the red color filter unit 321 on the substrate 100. The correspondence between the green color filter unit 322 and the green light-emitting unit 212 means that the orthographic projection of the green light-emitting unit 212 on the substrate 100 at least partially overlaps with the orthographic projection of the green color filter unit 322 on the substrate 100. The correspondence between the blue color filter unit 323 and the blue light-emitting unit 213 means that the orthographic projection of the blue light-emitting unit 213 on the substrate 100 at least partially overlaps with the orthographic projection of the blue color filter unit 323 on the substrate 100.

In some embodiments, the orthographic projection of the red color filter unit 321 on the substrate 100 covers the orthographic projection of the red light-emitting unit 211 on the substrate 100. Similarly, the orthographic projection of the green color filter unit 322 on the substrate 100 covers the orthographic projection of the green light-emitting unit 212 on the substrate 100. The orthographic projection of the blue color filter unit 323 on the substrate 100 covers the orthographic projection of the blue light-emitting unit 213 on the substrate 100.

There are various ways to set the first wavelength band and the second wavelength band, which can be configured by the user according to actual needs. For example, when a photosensitive element is disposed on the non-display side of the display module 10, the photosensitive element is used to capture light within the first wavelength band. For instance, when the photosensitive element is an infrared photosensitive element, the light within the first wavelength band can be infrared light. When the sensing element is another module such as a fingerprint recognition module, the first wavelength band can also be light within other wavelength ranges, for example, the light within the first wavelength band can be red light. The second wavelength band and the first wavelength band only need to be at least partially non-overlapping. For example, the second wavelength band can be light in all wavelength bands except the first wavelength band, such as light other than red light. In one embodiment, the second wavelength band can be light in partial wavelength bands except the first wavelength band, for example, the light within the second wavelength band can be blue light and/or green light. In one embodiment, the second wavelength band can be light within the visible spectrum except the first wavelength band.

Due to the phenomenon of gradual color transition between lights of different colors, their wavelength bands are also not identical. Therefore, when categorizing colors, it is not possible to strictly divide wavelength bands into distinct ranges based solely on color; there may be regions where the wavelength bands of different colored lights partially overlap. For example, when the light within the first wavelength band is infrared light and the second wavelength band is red light, the wavelength bands of infrared light and red light are close. For instance, when the filling unit 330 performs filtering, some red light near the infrared wavelength band might also pass through the filling unit 330, which could cause partial overlap between the first and second wavelength bands. When the light within the first wavelength band is infrared light and the light within the second wavelength band is blue light, the difference between the infrared and blue wavelength bands is large, and in this case, the first and second wavelength bands do not overlap. In one embodiment, when there are multiple filling units 330, it is possible that all filling units 330 allow light within the first wavelength band to pass through while filtering light within the second wavelength band. In one embodiment, a single filling unit 330 may allow light within the first wavelength band to pass through while filtering light within the second wavelength band, and the first wavelength bands corresponding to different filling units 330 may be the same or different.

There are various ways to set the material of the filling unit 330, as long as the filling unit 330 allows light within the first wavelength band to pass through and filters light within the second wavelength band.

In some embodiments, the material of the filling unit 330 is the same as the material of at least a portion of the color filter units 320.

In these optional embodiments, the material of the filter unit 320 has the function of allowing light within a preset wavelength band to pass through while filtering light within certain wavelength bands. The material of the filling unit 330 is the same as that of the filter unit 320. On one hand, this enables the function of the filling unit 330; on the other hand, it allows the filling unit 330 and at least part of the filter unit 320 to be formed in the same process step, thereby simplifying the manufacturing process of the display module.

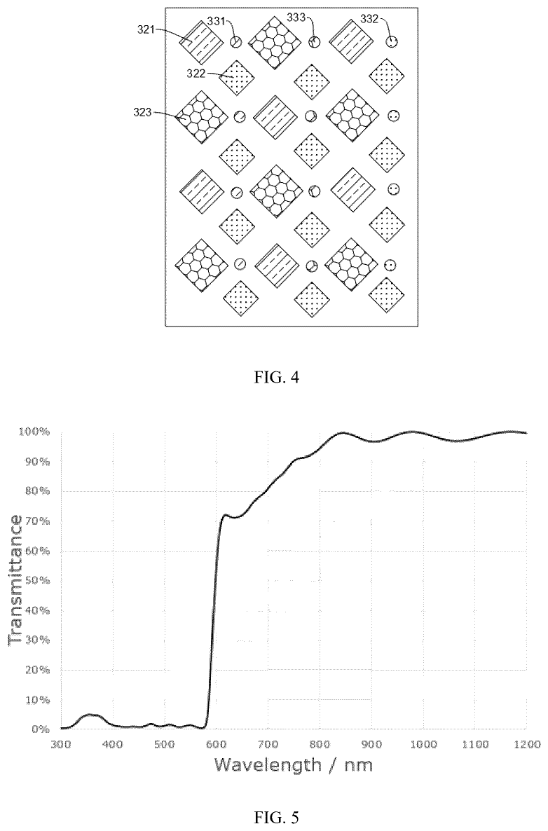

As described above, please refer to FIGS. 3 and 4 together. In one embodiment, the filter unit 320 includes a red filter unit 321, a green filter unit 322, and a blue filter unit 323. The filling unit 330 may include at least one of a red filling unit 331, a green filling unit 332, and a blue filling unit 333. The material of the red filling unit 331 is the same as that of the red filter unit 321, the material of the green filling unit 332 is the same as that of the green filter unit 322, and the material of the blue filling unit 333 is the same as that of the blue filter unit 323.

In these optional embodiments, the red filling unit 331 can be prepared using the same material as the red filter unit 321, the green filling unit 332 can be prepared using the same material as the green filter unit 322, and the blue filling unit 333 can be prepared using the same material as the blue filter unit 323, which can simplify the manufacturing process of the display module.

In one embodiment, when the filling unit 330 includes a red filling unit 331, the red filling unit 331 primarily allows light within the wavelength range of 625 nm to 740 nm to pass through and filters out other visible light.

In one embodiment, when the filling unit 330 includes a green filling unit 332, the green filling unit 332 primarily allows light within the wavelength range of 490 nm to 580 nm to pass through and filters out other visible light.

In one embodiment, when the filling unit 330 includes a blue filling unit 333, the blue filling unit 333 primarily allows light within the wavelength range of 440 nm to 475 nm to pass through and filters out other visible light.

In some embodiments, as described above, when the photosensitive element is an infrared photosensitive element, the light within the first wavelength band is infrared light, enabling the filling unit 330 to allow infrared light to pass through without affecting the infrared photosensitive element's ability to acquire light information.

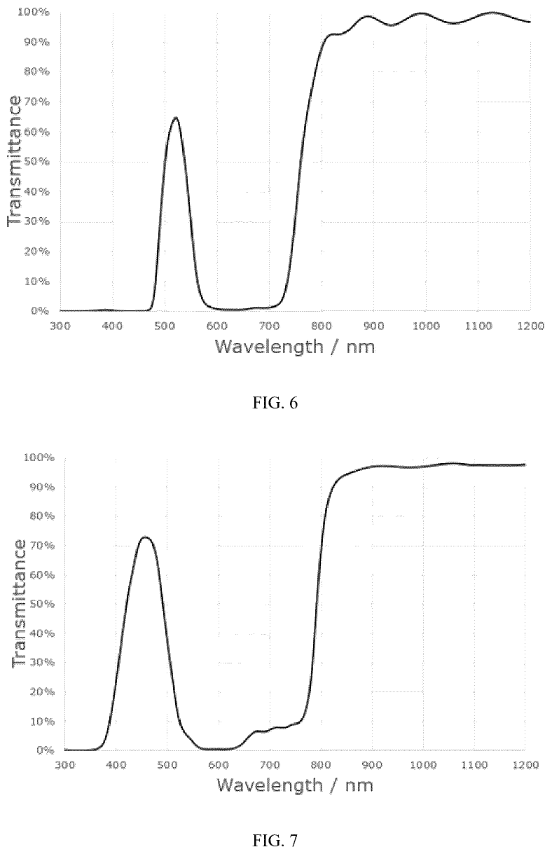

As shown in FIGS. 5 to 7, the horizontal axis in FIG. 5 represents wavelength, and the vertical axis represents the transmittance of the red filling unit 331 to light of different wavelengths. The horizontal axis in FIG. 6 represents wavelength, and the vertical axis represents the transmittance of the green filling unit 332 to light of different wavelengths. The horizontal axis in FIG. 7 represents wavelength, and the vertical axis represents the transmittance of the blue filling unit 333 to light of different wavelengths. When the light within the first wavelength band is infrared light, the filling unit 330 may simultaneously include a red filling unit 331, a green filling unit 332, and a blue filling unit 333. The red filling unit 331, green filling unit 332, and blue filling unit 333 all exhibit good transmittance for wavelengths above 750 nm, meaning they all effectively allow infrared light to pass through while filtering out some visible light other than infrared light.

In these optional embodiments, on one hand, the filling unit 330 allows infrared light to pass through without affecting the use of the photosensitive element; on the other hand, the display effect of the filling unit 330 is similar to that of the filter unit 320, which can improve the display effect of the display module in the screen-off state. For display modules in related technologies, photosensitive elements are provided on the back side of the display module to acquire light information through the display module. To improve the light transmittance of the display module, openings need to be made in the light-shielding portion 310. If the openings are not filled with material or are filled with transparent material, all light can pass through the openings, while other areas consist of filter units 320 or the light-shielding portion 310. In the screen-off state, the display difference between the openings filled with transparent material or left unfilled and other areas is significant, affecting the display effect of the display module in the screen-off state.

In one embodiment, the filling unit 330 includes a red filling unit 331, and at least one red filling unit 331 is adjacent to a red filter unit 321 to improve the display effect of the display module in the screen-off state.

In one embodiment, the filling unit 330 includes a green filling unit 332, and at least one green filling unit 332 is adjacent to a green filter unit 322 to improve the display effect of the display module in the screen-off state.

In one embodiment, the filling unit 330 includes a blue filling unit 333, and at least one blue filling unit 333 is adjacent to a blue filter unit 323 to improve the display effect of the display module in the screen-off state.

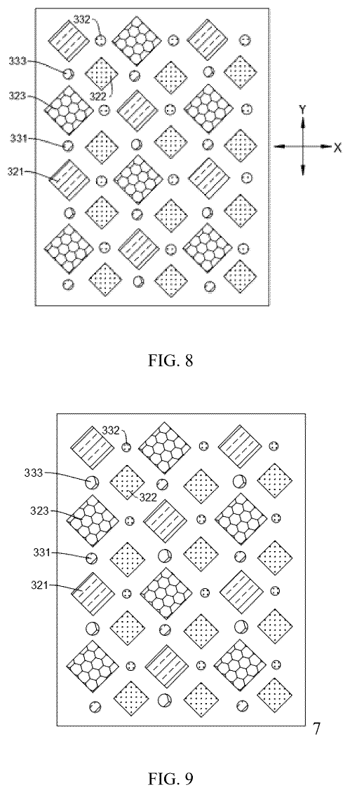

In one embodiment, as shown in FIG. 8, when the filling unit 330 includes a red filling unit 331, a green filling unit 332, and a blue filling unit 333, the arrangement of the red filling unit 331, green filling unit 332, and blue filling unit 333 is the same as that of the red filter unit 321, green filter unit 322, and blue filter unit 323.

For example, as shown in FIG. 8, when the filter unit 320 includes a first group of filter structures and a second group of filter structures alternately arranged along a first direction X, the first group of filter structures includes blue filter units 323 and red filter units 321 alternately arranged along a second direction Y, and the second group of filter structures includes green filter units 322 sequentially arranged along the second direction Y, the filling unit 330 includes a first group of filling structures and a second group of filling structures alternately arranged along the first direction X, the first group of filling structures includes blue filling units 333 and red filling units 331 alternately arranged along the second direction Y, and the second group of filling structures includes green filling units 332 sequentially arranged along the second direction Y. That is, the arrangement pattern of the red filling units 331, the green filling units 332, and the blue filling units 333 is the same as the arrangement pattern of the red filter units 321, the green filter units 322, and the blue filter units 323, to improve the influence of providing the filling unit 330 on the display effect of the display module. The first direction X is any direction on the plane where the filter layer 300 is located, the second direction Y intersects the first direction X, and the second direction Y is also located on the plane where the filter layer 300 is located. In some embodiments, the first direction X is perpendicular to the second direction Y.

In one embodiment, in the above embodiments, the blue filling unit 333 may be located between the blue filter unit 323 and the red filter unit 321 sequentially arranged along the second direction Y, the red filling unit 331 may be located between the red filter unit 321 and the blue filter unit 323 sequentially arranged along the second direction Y, and the green filling unit 332 may be located between two adjacent green filter units 322 along the second direction Y.

In some embodiments, the photosensitive element may also be a fingerprint recognition element, which is used to recognize light emitted by the light-emitting unit 210 and reflected back after reaching a finger. In this case, the light within the first wave may be light emitted by at least one light-emitting unit 210.

In the above embodiments, in one embodiment, the filling unit 330 may include a green filling unit 332. The material of the green filling unit 332 is the same as that of the green filter unit 322, and the green filling unit 332 allows green light to pass through and filters other stray light.

In one embodiment, the filling unit 330 includes a red filling unit 331, a green filling unit 332, and a blue filling unit 333. The red filling unit 331 allows light emitted by the red light-emitting unit 211 to pass through and filters other light, the green filling unit 332 allows light emitted by the green light-emitting unit 212 to pass through and filters other light, and the blue filling unit 333 allows light emitted by the blue light-emitting unit 213 to pass through and filters other light. This can increase the amount of light passing through the filling unit 330 and improve the recognition accuracy of the photosensitive element.

In some embodiments, when the filling unit 330 includes a red filling unit 331, a green filling unit 332, and a blue filling unit 333, the ratio of the total area of the red filling unit 331 to the total area of the green filling unit 332 is the same as the ratio of the total area of the red filter unit 321 to the total area of the green filter unit 322.

In these optional embodiments, the sum of the areas of all red filling units 331 is A, the sum of the areas of all green filling units 332 is B; the sum of the areas of all red filter units 321 is a, the sum of the areas of all green filter units 322 is b, and A:B=a:b.

Similarly, in some embodiments, the ratio of the total area of the red filling unit 331 to the total area of the blue filling unit 333 is the same as the ratio of the total area of the red filter unit 321 to the total area of the blue filter unit 323.

In some embodiments, the ratio of the total area of the green filling unit 332 to the total area of the blue filling unit 333 is the same as the ratio of the total area of the green filter unit 322 to the total area of the blue filter unit 323.

In some embodiments, as shown in FIG. 9, when the filling unit 330 includes a red filling unit 331, a green filling unit 332, and a blue filling unit 333, the ratio of the total area of the red filling unit 331, the total area of the green filling unit 332, and the total area of the blue filling unit 333 is the same as the ratio of the total area of the red filter unit 321, the total area of the green filter unit 322, and the total area of the blue filter unit 323.

In these optional embodiments, the ratio between the total areas of filling units 330 of different colors is the same as the ratio between the total areas of filter units 320 of different colors. For example, the sum of the areas of all red filling units 331 is M, the sum of the areas of all green filling units 332 is N, and the sum of the areas of all blue filling units 333 is K; the sum of the areas of all red filter units 321 is m, the sum of the areas of all green filter units 322 is n, and the sum of the areas of all blue filter units 323 is k; and M:N:K=m:n:k. By setting the area distribution of the filling units 330 according to the area distribution of the filter units 320, more light emitted from the filter units 320 and reflected by the user's fingertip can pass through the filling units 330, thereby improving the recognition accuracy of the photosensitive element. In addition, it can also ensure the display effect of the display module 10 in the screen-off state.

In one embodiment, the ratio between the total area of multiple red filling units 331, the total area of multiple green filling units 332, and the total area of multiple blue filling units 333 may be the same as the ratio between the total area of multiple red filter units 321, the total area of multiple green filter units 322, and the total area of multiple blue filter units 323.

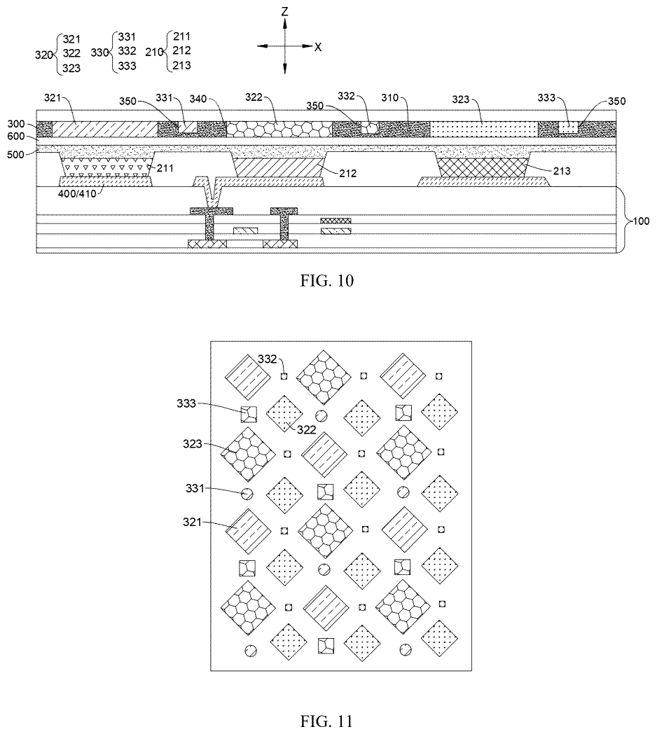

In one embodiment, the accommodating recesses 350 for accommodating individual red filling units 331, the accommodating recesses 350 for accommodating individual green filling units 332, and the accommodating recesses 350 for accommodating blue filling units 333 have the same size but different quantities, and the ratio among the total area of the multiple red filling units 331, the total area of the multiple green filling units 332, and the total area of the multiple blue filling units 333 is the same as the ratio among the total area of the multiple red filter units 321, the total area of the multiple green filter units 322, and the total area of the multiple blue filter units 323. For example, if the total area of the blue filter units 323 is larger, the number of accommodating recesses 350 for accommodating blue filling units 333 can be set to be greater, resulting in a larger number of blue filling units 333, and the area ratio among the filling units 330 of different colors is the same as the area ratio among the filter units 320 of different colors. In these embodiments, the accommodating recesses 350 have the same size, which can further reduce display differences in different regions in the screen-off state. It is worth noting that the same size of the accommodating recesses 350 means that the size and shape structure of the accommodating recesses 350 are identical. In one embodiment, in other embodiments, it is also possible that the area ratio between a single filling unit and a single filter unit of the same color is the same, i.e., the area ratio among a single red filling unit 331, a single green filling unit 332, and a single blue filling unit 333 is the same as the area ratio among a single red filter unit 321, a single green filter unit 322, and a single blue filter unit 323. This allows light to pass through the filling units 330 of different colors more uniformly. In one embodiment, in the above embodiments, the arrangement of the red filling units 331, green filling units 332, and blue filling units 333 is the same as the arrangement of the red filter units 321, green filter units 322, and blue filter units 323. This ensures that when light emitted from the filter units 320 is reflected back to the filling units 330 by the user's fingertip, light emitted from the red filter units 321 is more likely to be reflected to the red filling units 331, light emitted from the green filter units 322 is more likely to be reflected to the green filling units 332, and light emitted from the blue filter units 323 is more likely to be reflected to the blue filling units 333, thereby further increasing the amount of light passing through the filling units 330 and improving the recognition accuracy of the photosensitive element. In some embodiments, as shown in <FIG. 3>, the accommodating recess 350 may be a through groove, i.e., the accommodating recess 350 penetrates through the light-shielding portion 310. For example, the dimension of the filling unit 330 in the thickness direction Z is the same as the dimension of the light-shielding portion 310 in the thickness direction Z. This can better improve the light transmittance in the region where the accommodating recess 350 is located. In one embodiment, in other embodiments, as shown in <FIG. 10>, the accommodating recess 350 may also be a blind groove. For example, the accommodating recess 350 does not penetrate through the light-shielding portion 310 and is formed by recessing from the surface of the light-shielding portion 310 facing and/or away from the substrate 100. The thickness in the region where the accommodating recess 350 is located is smaller, which can improve the light transmittance in that region. When the accommodating recess 350 is a blind groove, in one embodiment, the thickness at the bottom of the accommodating recess 350 is greater than 0 and less than or equal to 0.35 μm. A smaller thickness at the bottom of the accommodating recess 350 can ensure the light transmittance in the region where the accommodating recess 350 is located. For example, the thickness at the bottom of the accommodating recess 350 can be 0.02 μm, 0.05 μm, 0.08 μm, 0.1 μm, . . . , 0.2 μm, 0.24 μm, . . . , 0.34 μm, 0.35 μm. As shown in <FIG. 1>, the display module has a first display area AA1, a second display area AA2, and a non-display area NA surrounding the first display area AA1 and the second display area AA2. The light transmittance of the first display area AA1 is greater than that of the second display area AA2. In one embodiment, in other embodiments, the display module is a full-screen display, and the display module does not include a non-display area NA. In the display module provided by the embodiments of the present application, the display module has a first display area AA1 and a second display area AA2. In some embodiments, the aperture ratio of the filling unit 330 is greater than or equal to 2.5% and less than or equal to 9.5%. The aperture ratio of the filling unit 330 can be set, for example, to 2.5%, 2.6%, 3.4%, 3.5%, 8.07%, 8.85%, 9.5%, etc. For example, if the light transmittance of the first display area AA1 is greater than that of the second display area AA2, then the filling unit 330 is disposed in the first display area AA1, and the aperture ratio of the filling unit 330 refers to the ratio of the area of the filling unit 330 to the total area of the first display area AA1. In one embodiment, if the light transmittance of the first display area AA1 is the same as that of the second display area AA2, the filling unit 330 can be disposed in both the first display area AA1 and the second display area AA2, and the aperture ratio of the filling unit 330 refers to the ratio of the area of the filling unit 330 to the total area of the first display area AA1 and the second display area AA2. In these optional embodiments, when the aperture ratio of the filling unit 330 is within the above range, it can both improve the situation where an excessively small aperture ratio of the filling unit 330 results in too little light passing through the filling unit 330, affecting the operation of the photosensitive element, and improve the situation where an excessively large aperture ratio of the filling unit 330 affects the distribution area of the filter units 320 and thus the display effect of the display module 10. In one embodiment, the orthographic projection of each light-emitting unit 210 on the substrate 100 is located within the orthographic projection of each filter unit 320 on the substrate 100, and more light can be emitted through the filter units 320 to improve the display effect of the display module 10. In one embodiment, the orthographic projection of the light-emitting unit 210 on the substrate 100 is offset from the orthographic projection of each filling unit 330 on the substrate 100. This helps prevent light incident on the filling unit 330 from entering the light-emitting unit 210 and affecting its display effect.

Please also refer to FIG. 9 and FIG. 11. There are various ways to set the shape of the recess 350. As shown in FIG. 9, if the orthographic projection shape of the recess 350 on the substrate 100 is circular, then the orthographic projection shape of the filling unit 330 on the substrate 100 is circular. In one embodiment, as shown in FIG. 11, if at least a portion of the orthographic projection shape of the recess 350 on the substrate 100 is rectangular, then the orthographic projection shape of the filling unit 330 on the substrate 100 is rectangular. In one embodiment, the orthographic projection shape of the recess 350 on the substrate 100 may also be polygonal, irregular, or other shapes, and correspondingly, the orthographic projection shape of the filling unit 330 on the substrate 100 is polygonal, irregular, or other shapes. The orthographic projection shapes of multiple recesses 350 on the substrate 100 may be the same or different. The orthographic projection shapes of multiple recesses 350 corresponding to filling units 330 of the same color on the substrate 100 may be the same or different.

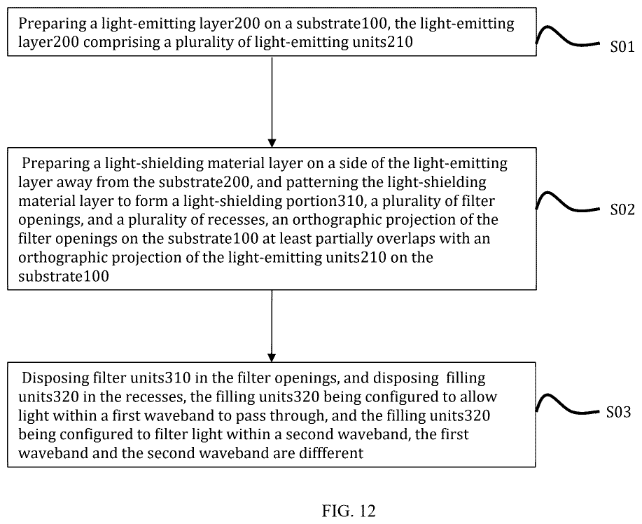

Please refer to FIG. 12. An embodiment of the second aspect of the present application further provides a method for fabricating a display module. The display module may be the display module according to any embodiment of the first aspect described above. Please also refer to FIG. 1 to FIG. 12. The method for fabricating the display module includes:

Step S01: Form a light-emitting layer 200 on a substrate 100, the light-emitting layer 200 including a plurality of light-emitting units 210.

In one embodiment, a pixel definition layer may first be formed on the substrate 100 to define pixel defining portions and pixel openings, and then the light-emitting units 210 are formed by evaporation within the pixel openings.

Step S02: Form a light-shielding material layer on a side of the light-emitting layer 200 away from the substrate 100, and pattern the light-shielding material layer to form a light-shielding portion 310, filter openings 340, and recesses 350. The orthographic projection of the filter openings 340 on the substrate 100 at least partially overlaps with the orthographic projection of the light-emitting units 210 on the substrate 100.

Step S03: Dispose filter units 320 within the filter openings 340, and dispose filling units 330 within the recesses 350. The filling units 330 are configured to allow light within a first wavelength band to pass through and to filter light within a second wavelength band. The first wavelength band and the second wavelength band at least partially do not overlap.

In one embodiment, the positions and dimensions of the recesses 350 are the same as the positions and dimensions of the filling units 330, and thus are not repeatedly labeled in the drawings.

In the display module 10 fabricated according to the embodiments of the present application, the light-emitting units 210 are used for light emission to achieve light-emitting display of the display module 10. The filter layer 300 includes the light-shielding portion 310 and the filter units 320. The filter units 320 can filter stray light, improving the display effect of the display module 10. The recesses 350 in the light-shielding portion 310 are further provided with filling units 330. The filling units 330 can allow light within the first wavelength band to pass through, thereby improving the light transmittance of the display module 10. When a photosensitive element is disposed on the non-display side of the display module 10, the photosensitive element can acquire light information within the first wavelength band passing through the filling units 330, without affecting the normal operation of the photosensitive element.

Furthermore, the filling units 330 can also filter light within the second wavelength band, enabling the filling units 330 to hinder the propagation of at least a portion of the light within the second wavelength band. When the display module 10 is in a screen-off state, this can reduce the display difference between the area where the filling units 330 are located and other areas, improving the display effect of the display module 10 in the screen-off state. Therefore, by disposing the filling units 330 within the recesses 350, the present application can not only ensure the light transmittance of the display module 10 but also guarantee the display effect of the display module 10 in the screen-off state.

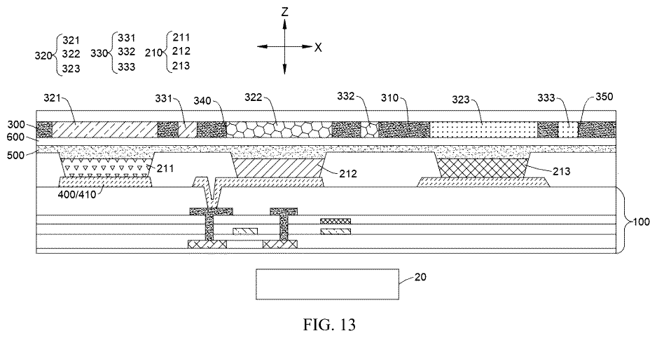

Please refer to FIG. 13. An embodiment of the third aspect of the present application further provides a display device. The display device includes the display module 10 according to any embodiment of the first aspect described above and a photosensitive element 20. The photosensitive element 20 is disposed on a side of the substrate 100 away from the light-emitting layer 200. The photosensitive element 20 is configured to receive light information within the first wavelength band. Since the display device provided by the embodiment of the third aspect of the present application includes the display module 10 according to any embodiment of the first aspect described above, the display device provided by the embodiment of the third aspect of the present application has the beneficial effects of the display module 10 according to any embodiment of the first or second aspect, which will not be repeated here.

In one embodiment, the photosensitive element 20 includes at least one of a fingerprint recognition sensor and an infrared sensor.

Although the present application has been described with reference to preferred embodiments, various modifications can be made and equivalents may be substituted for components thereof without departing from the scope of the present application. In particular, as long as there is no structural conflict, the various technical features mentioned in the embodiments can be combined in any manner. The present application is not limited to the specific embodiments disclosed herein but includes some embodiments falling within the scope of the claims.

What is claimed is:

1. A display module, comprising:
a substrate;
a light-emitting layer disposed on one side of the substrate, the light-emitting layer comprising a plurality of light-emitting units;
a filter layer disposed on a side of the light-emitting layer away from the substrate, the filter layer comprising a light-shielding portion and a plurality of filter openings;
a plurality of filter units disposed within the filter openings, an orthographic projection of the filter units on the substrate at least partially overlapping with an orthographic projection of the light-emitting units on the substrate; and
a plurality of recesses provided in the light-shielding portion,
wherein a plurality of filling units are disposed within the recesses, the filling units are configured to allow light within a first wavelength band to pass through and to filter light within a second wavelength band, the first wavelength band and the second wavelength band at least partially not overlap.

2. The display module according to claim 1, wherein a material of the filling units is the same as a material of at least a portion of the filter units.

3. The display module according to claim 2, wherein the filter units comprise a plurality of red filter units, a plurality of green filter units, and a plurality of blue filter units, and each of the filling units comprises at least one of a red filling unit, a green filling unit, and a blue filling unit; a material of the red filling units is the same as a material of the red filter units, a material of the green filling units is the same as a material of the green filter units, and a material of the blue filling units is the same as a material of the blue filter units.

4. The display module according to claim 3, wherein light within the first wavelength band is infrared light.

5. The display module according to claim 4, wherein the filling units comprise a plurality of red filling units, and at least one of the red filling units is adjacent to one of the red filter units.

6. The display module according to claim 4, wherein the filling units comprise a plurality of green filling units, and at least one of the green filling units is adjacent one of to the green filter units.

7. The display module according to claim 4, wherein the filling units comprise a plurality of blue filling units, and at least one of the blue filling units is adjacent to one of the blue filter units.

8. The display module according to claim 4, wherein the filling units comprise a plurality of red filling units, a plurality of green filling units, and a plurality of blue filling units, and an arrangement manner of the red filling units, the green filling units, and the blue filling units is the same as an arrangement manner of the red filter units, the green filter units, and the blue filter units.

9. The display module according to claim 8, wherein the filter units comprise a first group of filter structure and a second group of filter structure alternately arranged along a first direction, the first group of filter structure comprises the blue filter units and the red filter units alternately arranged along a second direction, and the second group of filter structure comprises the green filter units sequentially arranged along the second direction; the filling units comprise a first group of filling structure and a second group of filling structure alternately arranged along the first direction, the first group of filling structure comprises the blue filling units and the red filling units alternately arranged along the second direction, and the second group of filling structure comprises green filling units sequentially arranged along the second direction; the first direction intersects the second direction.

10. The display module according to claim 3, wherein light within a first waveband is light emitted by at least one of the light-emitting units, the filling units comprise the green filling units; or, the filling units comprise the red filling units, the green filling units, and the blue filling units.

11. The display module according to claim 10, wherein the filling units comprise the red filling units, the green filling units, and the blue filling units, a ratio of a total area of the red filling units and the green filling units is the same as a ratio of a total area of the red filter units and the green filter units; or, a ratio of a total area of the red filling units and the blue filling units is the same as a ratio of a total area of the red filter units and the blue filter units; or, a ratio of a total area of the green filling units and the blue filling units is the same as a ratio of a total area of the green filter units and the blue filter units.

12. The display module according to claim 10, wherein the filling units comprise the red filling units, the green filling units, and the blue filling units, a ratio of a total area of the red filling units, the green filling units, and the blue filling units is the same as a ratio of a total area of the red filter units, the green filter units, and the blue filter units.

13. The display module according to claim 10, wherein a ratio of an area of a single red filling unit, an area of a single green filling unit, and an area of a single blue filling unit is the same as a ratio of an area of a single red filter unit, an area of a single green filter unit, and an area of a single blue filter unit.

14. The display module according to claim 1, wherein the recesses penetrate through the light-shielding portion; or, the recesses are blind grooves.

15. The display module according to claim 14, wherein the recesses are blind grooves, and a thickness at a bottom of the recesses is greater than 0 and less than or equal to 0.35 μm.

16. The display module according to claim 1, wherein an aperture ratio of the filling units is greater than or equal to 2.5% and less than or equal to 9.5%.

17. The display module according to claim 1, wherein the display module has a first display area, a second display area, and a non-display area surrounding the first display area and the second display area, a light transmittance of the first display area is greater than a light transmittance of the second display area; the filling units are disposed in the first display area.

18. A method for preparing a display module, comprising:
preparing a light-emitting layer on a substrate, the light-emitting layer comprising a plurality of light-emitting units;
preparing a light-shielding material layer on a side of the light-emitting layer away from the substrate, and patterning the light-shielding material layer to form a light-shielding portion, a plurality of filter openings, and a plurality of recesses, an orthographic projection of the filter openings on the substrate at least partially overlaps with an orthographic projection of the light-emitting units on the substrate;
disposing filter units in the filter openings, and disposing filling units in the recesses, the filling units being configured to allow light within a first waveband to pass through, and the filling units being configured to filter light within a second waveband, the first waveband and the second waveband at least partially not overlapping.

19. A display device, comprising:
a display module which comprising:
a substrate;
a light-emitting layer disposed on one side of the substrate, the light-emitting layer comprising a plurality of light-emitting units;
a filter layer disposed on a side of the light-emitting layer away from the substrate, the filter layer comprising a light-shielding portion and a plurality of filter openings;
a plurality of filter units are disposed within the filter openings, and an orthographic projection of the filter units on the substrate at least partially overlapping with an orthographic projection of the light-emitting units on the substrate; and
a plurality of recesses are provided in the light-shielding portion,
wherein filling units are disposed within the recesses, the filling units being configured to allow light within a first wavelength band to pass through and to filter light within a second wavelength band, the first wavelength band and the second wavelength band at least partially not overlap;
a photosensitive element, disposed on a side of the substrate away from the light-emitting layer, the photosensitive element being configured to receive light information of a first waveband.

20. The display device according to claim 19, wherein the photosensitive element comprises at least one of a fingerprint recognition sensor and an infrared sensor.
